(19) United States
(12) Patent Application Publication
(10) Pub. No.: US 2021/0060528 A1
(43) Pub. Date: Mar. 4, 2021

(54) METAL REMOVAL AGENT AND METAL REMOVAL METHOD FOR REMOVING METAL IMPURITIES IN SOLUTION

(71) Applicant: NISSAN CHEMICAL CORPORATION, Tokyo (JP)

(72) Inventors: Hiroaki YAGUCHI, Toyama-shi (JP); Shun KUBODERA, Toyama-shi (JP); Gun SON, Toyama-shi (JP)

(73) Assignee: NISSAN CHEMICAL CORPORATION, Tokyo (JP)

(21) Appl. No.: 16/958,050

(22) PCT Filed: Dec. 25, 2018
(86) PCT No.: PCT/JP2018/047565

§ 371 Date: Jun. 25, 2020

(30) Foreign Application Priority Data
Dec. 25, 2017 (JP) 2017-248245

(51) Int. Cl. B01J 20/26; C02F 1/28; C02F 1/62; B01D 15/38; B01J 20/10

(52) U.S. Cl. CPC B01J 20/267; C02F 1/281; C02F 1/62; B01D 15/3828; B01J 2220/58; B01D 2257/60; B01D 2259/40; B01J 2220/445; B01J 20/103

(57) ABSTRACT

A metal adsorption agent including a chelating agent (A) and a chelating agent (B), wherein the chelating agent (A) is a metal adsorption agent containing a carrier having a glucamine-type functional group, and the chelating agent (B) is a metal adsorption agent containing a carrier having a thiol group, a thiourea group, an amino group, a triazabicyclodecene-inducing group, a thiouronium group, an imidazole group, a sulfonate group, a hydroxy group, an aminoacetate group, an amidoxime group, an aminophosphate group, or any combination of these groups. The carrier of each of the chelating agent (A) and the chelating agent (B) may be silica, a silica component-containing substance, polystyrene, or crosslinked porous polystyrene. The solution may contain water or an organic solvent.

### TECHNICAL FIELD

The present invention relates to a metal removal agent for removing metal impurities contained in a solvent, and to a method for removing the metal impurities.

### BACKGROUND ART

A composition containing many chemical substances is applied to the manufacture of a product used for electronic parts or semiconductor production. For example, in the case of a resist film-forming composition or resist underlayer film-forming composition used in a lithographic process for semiconductor production, a trace amount of metal ions remaining in such a composition or a metal- or metal oxide-derived electrically charged colloidal substance contained in the composition may have an unexpected adverse effect on a final product, or on the lithographic process or etching process during production of the product.

The aforementioned chemical substance may be an impurity derived from a raw material, or may be a remaining metal catalyst used for an organic reaction. In many cases, such a metal component can be removed with an ion-exchange resin if the metal component is an alkali metal or an alkaline earth metal.

However, the metal component is in the form of metal ions or electrically charged metal oxide colloidal particles. Polyvalent metal ions derived from a heavy metal may form electrically charged colloidal particles in an organic solvent from the effect of a trace amount (on the order of ppm) of water.

The aforementioned polyvalent metal ions or electrically charged metal oxide colloidal particles derived from the metal are not readily removed with the ion-exchange resin by adsorption.

A chelating resin is used for removal of the metal ions or the colloidal particles (see Patent Documents 1 and 2)

### PRIOR ART DOCUMENTS

### Patent Documents

Patent Document 1: International Publication WO 2015/146307

Patent Document 2: Japanese Unexamined Patent Application Publication (Translation of PCT Application) No. 2008-502470 (JP 2008-502470 A)

### SUMMARY OF THE INVENTION

### Problems to be Solved by the Invention

In general, an ion-exchange resin is used for removal of metal components. However, it is undesirable that a metal removing method using a sulfonyl-group-containing cationic ion-exchange resin be applied to an ionic material, since when the ionic material is contained in a coating material composition used for a semiconductor production process, a cationic component is adsorbed by the ion-exchange resin, resulting in a significant reduction in yield. It is also undesirable that the sulfonyl-group-containing cationic ion-exchange resin be used for removal of a metal from a material containing an acid-unstable (denaturation) group, since the ion-exchange resin may denature the material. The method described in Patent Document 1 or 2 may pose problems in that metal ions or electrically charged metal oxide colloidal particles have different ionic strengths, ionic radii, or particle diameters, and a chelating resin has a macromolecular structure that does not fit the form of the aforementioned ionic metal species depending on the type of the functional group of the chelating resin and thus insufficiently exhibits its metal adsorption ability.

An object of the present invention is to remove metal impurities (e.g., polyvalent metals, polyvalent metal ions, or electrically charged metal oxide colloidal particles derived therefrom) from a coating composition used for a semiconductor production process (which composition contains a to-be-purified material dissolved therein) by using a metal adsorption agent containing not a single chelating resin but a combination of specific chelating resins without causing adsorption or denaturation of components (other than the impurities) contained in the composition, to thereby prepare a purified material composition having high purity.

### Means for Solving the Problems

A first aspect of the present invention is a metal adsorption agent for removing metal impurities contained in a solution, the metal adsorption agent comprising a chelating agent (A) and a chelating agent (B), wherein

the chelating agent (A) is a metal adsorption agent containing a carrier having a glucamine-type functional group, and

the chelating agent (B) is a metal adsorption agent containing a carrier having a thiol group, a thiourea group, an amino group, a triazabicyclodecene-inducing group, a thiouronium group, an imidazole group, a sulfonate group, a hydroxy group, an aminoacetate group, an amidoxime group, an aminophosphate group, or any combination of these groups.

A second aspect of the present invention is the metal adsorption agent according to the first aspect, wherein the carrier of each of the chelating agent (A) and the chelating agent (B) is silica, a silica component-containing substance, polystyrene, or crosslinked porous polystyrene.

A third aspect of the present invention is the metal adsorption agent according to the first or second aspect, wherein the chelating agent (A) is a metal adsorption agent containing a polymer substance having a unit structure of the following Formula (A-1):

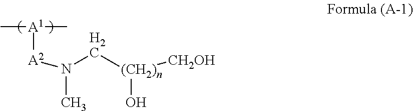

(wherein n is an integer of 1 to 10; A¹ is a unit structure forming silica, a silica component-containing substance, polystyrene, or crosslinked porous polystyrene serving as a carrier; A² is a single bond or a linking group that binds A¹ to the functional group; and the linking group is a C₁₋₁₀ alkylene group optionally containing an oxygen atom, a nitrogen atom, or a sulfur atom).

A fourth aspect of the present invention is the metal adsorption agent according to any one of the first to third aspects, wherein the chelating agent (B) is a metal adsorption agent containing a polymer substance having one or more unit structures selected from the group consisting of unit structures of the following Formulae (B-1) to (B-18):

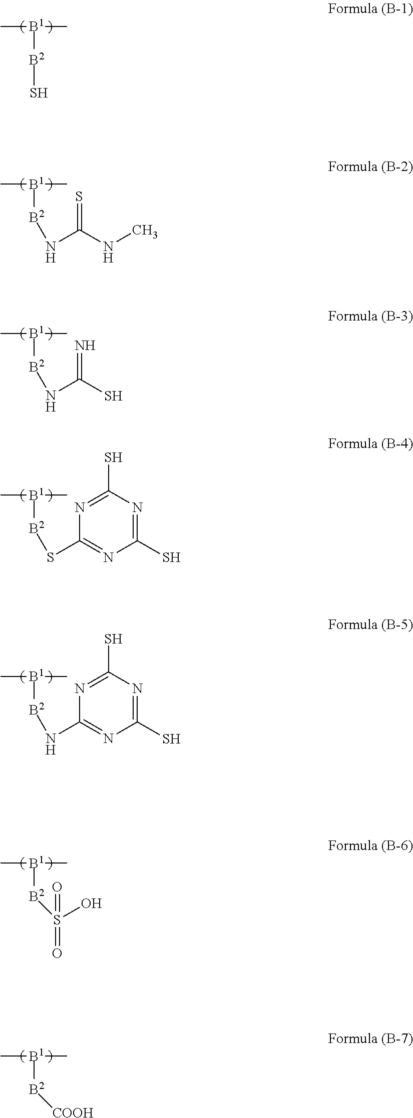

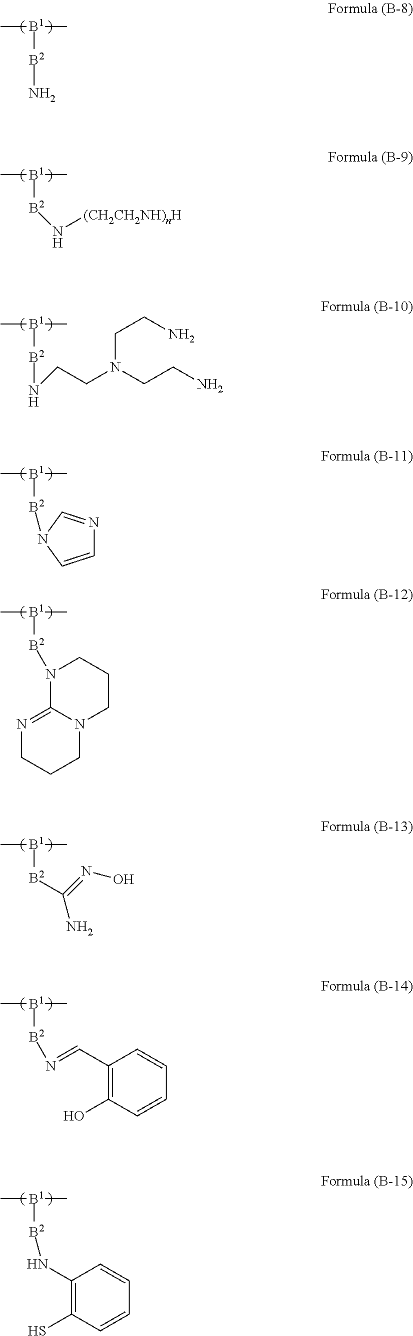

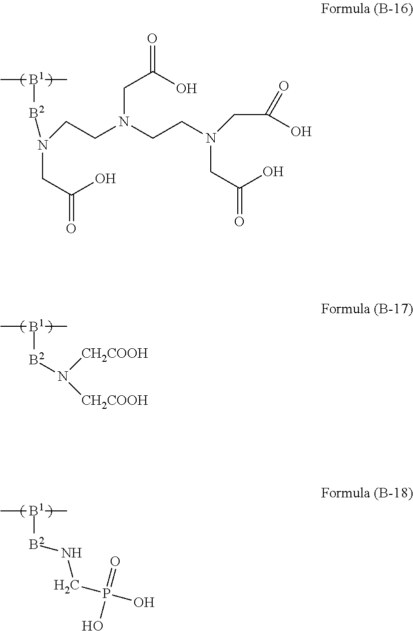

(wherein B¹ is a unit structure forming silica, a silica component-containing substance, polystyrene, or crosslinked porous polystyrene serving as a carrier; B² is a single bond or a linking group that binds B¹ to the functional group; and the linking group is a alkylene group optionally containing an oxygen atom, a nitrogen atom, or a sulfur atom).

A fifth aspect of the present invention is the metal adsorption agent according to any one of the first to fourth aspects, wherein the solution is a solution containing water or an organic solvent.

A sixth aspect of the present invention is the metal adsorption agent according to any one of the first to fifth aspects, wherein the metal adsorption agent comprises the chelating agent (A) and the chelating agent (B) in proportions by mass of 0.1 to 100:1.

A seventh aspect of the present invention is the metal adsorption agent according to any one of the first to sixth aspects, wherein the metal to be removed is a polyvalent metal belonging to periods 4 to 7 and groups 3 to 12, ions of the polyvalent metal, or a colloidal substance of a hydroxide or oxide of the metal.

An eighth aspect of the present invention is a material purification method comprising a step of preparing a to-be-purified material solution by dissolving or dispersing a to-be-purified material in a liquid; a step of causing the to-be-purified material solution to flow through a column filled with the metal adsorption agent according to any one of the first to seventh aspects, to thereby prepare a purified solution; and a step of obtaining a purified material from the purified solution.

A ninth aspect of the present invention is a method for producing a material solution containing a reduced amount of impurities, the method comprising a step of circulating a to-be-purified material solution containing a to-be-purified material dissolved or dispersed in a liquid in a system provided by connection with a pipe between a tank containing the to-be-purified material solution and a column filled with the metal adsorption agent according to any one of claims 1 to 7, to thereby remove, by adsorption, a polyvalent metal element, ions of the metal, or a colloidal substance of the metal contained in the to-be-purified material solution, thereby preparing a purified material solution containing a reduced amount of impurities.

A tenth aspect of the present invention is the method for producing a material solution containing a reduced amount of impurities according to the ninth aspect, wherein the liquid that dissolves or disperses the to-be-purified material is water or an organic solvent.

An eleventh aspect of the present invention is the method for producing a material solution containing a reduced amount of impurities according to the ninth or tenth aspect, wherein the to-be-purified material solution is circulated in a closed system.

A twelfth aspect of the present invention is the method for producing a material solution containing a reduced amount of impurities according to any one of the ninth to eleventh aspects, wherein the method comprises a step of causing the to-be-purified material solution to flow through an ion-exchange resin before and after causing the to-be-purified material solution to flow through the metal adsorption agent comprising the chelating agent (A) and the chelating agent (B).

A thirteenth aspect of the present invention is the method for producing a material solution containing a reduced amount of impurities according to any one of the ninth to twelfth aspects, wherein the liquid that dissolves or disperses the to-be-purified material is a previously purified liquid.

A fourteenth aspect of the present invention is the method for producing a material solution containing a reduced amount of impurities according to any one of the first to twelfth aspects, wherein the purification of the liquid is previously performed in a closed system for purifying the to-be-purified material solution containing the to-be-purified material, or the purification of the liquid is previously performed in a closed system different from the closed system described above, and the purified liquid is fed via a pipe to the closed system for purifying the to-be-purified material solution containing the to-be-purified material.

A fifteenth aspect of the present invention is the method for producing a material solution containing a reduced amount of impurities according to any one of the ninth to thirteenth aspects, wherein the to-be-purified material solution is a coating composition used in a lithographic process for semiconductor production.

A sixteenth aspect of the present invention is the method for producing a material solution containing a reduced amount of impurities according to any one of the ninth to fourteenth aspects, wherein the method is performed until the amount of the metal ions or the metal colloidal substance is reduced to 500 ppt or less in the to-be-purified material solution containing the to-be-purified material dissolved or dispersed in the liquid.

### Effects of the Invention

A composition containing many chemical substances is applied to the manufacture of a product used for electronic parts or semiconductor production. In the case of a resist film-forming composition or resist underlayer film-forming composition used in a lithographic process for semiconductor production, a trace amount of metal ions remaining in such a composition or a metal- or metal oxide-derived electrically charged colloidal substance contained in the composition may have an unexpected adverse effect on a final product, or on the lithographic process or etching process during production of the product. Thus, such metal impurities must be reduced to a level on the order of ppb or ppt.

In general, an ion-exchange resin is used for removal of metal components. However, in the case where an ionic material is contained in a coating material composition used for a semiconductor production process, a metal removing method using a sulfonyl-group-containing cationic ion-exchange resin cannot be applied to the ionic material, since a cationic component is adsorbed by the ion-exchange resin, resulting in a significant reduction in yield in the case where the ionic material is contained in the coating material composition used for the semiconductor production process. The sulfonyl-group-containing cationic ion-exchange resin cannot be applied to removal of a metal from a material containing an acid-unstable (denaturation) group, since the ion-exchange resin may denature the material.

Meanwhile, a method using a chelating resin may pose problems in that metal ions or electrically charged metal oxide colloidal particles have different ionic strengths, ionic radii, or particle diameters, and the chelating resin itself has a macromolecular structure that does not fit the form of the aforementioned ionic metal species depending on the type of the functional group of the chelating resin and thus insufficiently exhibits its metal adsorption ability.

The present invention involves the use of a metal adsorption agent containing a glucamine-type chelating agent in combination with a chelating agent having another functional group (e.g., a thiol group, a thiourea group, an amino group, an imidazole group, a sulfonate group, a hydroxyl group, or an aminoacetate group). According to the present invention, metal impurities (in particular, polyvalent metal ions, or electrically charged metal oxide colloidal particles containing such a metal) are adsorbed by the metal adsorption agent in a solution containing a to-be-purified substance dissolved or dispersed therein without causing adsorption or denaturation of a coating material composition used for a semiconductor production process. Thus, the metal impurities contained in the solution can be reduced to a very low level.

### MODES FOR CARRYING OUT THE INVENTION

The present invention is directed to a metal adsorption agent for removing metal impurities contained in a solution, the metal adsorption agent comprising a chelating agent (A) and a chelating agent (B).

The chelating agent (A) is a metal adsorption agent containing a carrier having a glucamine-type functional group, and the chelating agent (B) is a metal adsorption agent containing a carrier having a thiol group, a thiourea group, an amino group, a triazabicyclodecene-inducing group, a thiouronium group, an imidazole group, a sulfonate group, a hydroxy group, an aminoacetate group, an amidoxime group, an aminophosphate group, or any combination of these groups.

The metal adsorption agent of the present invention contains the chelating agent (A) in combination with the chelating agent (B). The chelating agent (B) may be a single chelating agent or a combination of two or more chelating agents. Each of the chelating agent (A) and the chelating agent (B) functions as a metal adsorption agent by itself.

In the chelating agent (A) and the chelating agent (B), the carrier may be, for example, silica, a silica component-containing substance, polystyrene, or crosslinked porous polystyrene. Thus, the chelating agent (A) or the chelating agent (B) is prepared by bonding of a chelating functional group (e.g., the aforementioned glucamine-type functional group or thiol group) to the surface of a carrier, such as silica, a silica component-containing substance, polystyrene, or crosslinked porous polystyrene. In the case of a porous carrier, the chelating functional group can be bonded to the interiors of pores. When the chelating functional group is bonded to the surface of the carrier, the chelating agent can efficiently come into contact with metal impurities in a solution.

The silica or the silica component-containing substance may be a synthetic or natural product. Preferably, the carrier does not elute impurities. From this viewpoint, the carrier may be, for example, synthetic quartz (SiO₂) produced by molding and baking of silica prepared through hydrolysis of a high-purity alkoxysilane. The silica component-containing substance may be, for example, forsterite (2MgO.SiO₂), zircon (ZrO₂.SiO₂), mullite (3Al₂O₃.2SiO₂), steatite (MgO.SiO₂), or cordierite (2MgO.2Al₂O₃.5SiO₂).

When the silica or the silica component-containing substance is modified with the chelating functional group, a silane coupling agent having a functional group capable of reacting with the end of the chelating functional group can be reacted with a silica component on the surfaces of particles of the silica or the silica component-containing substance, to thereby modify the particle surfaces and to introduce the chelating functional group. Examples of the functional group capable of reacting with the end of the chelating functional group include a vinyl group, an allyl group, a hydroxy group, a halogen group, an epoxy group, and a thiol group. The silane coupling agent may have one to three hydrolyzable groups (e.g., a methoxy group and an ethoxy group). The silane coupling agent may have three hydrolyzable groups in view of adhesion to the carrier.

The chelating agent prepared by bonding of the chelating functional group to silica particles may be charged into a column and used without any additional treatment. Alternatively, the chelating agent may be molded under application of an appropriate pressure and then charged into a column.

When polystyrene is modified with the chelating functional group, a chloromethyl group can be introduced to the surfaces of polystyrene particles by using a chloromethylation agent (e.g., chloromethyl methyl ether), and the chloromethyl group can be further reacted with the chelating functional group, to thereby introduce the chelating functional group to the polystyrene.

The chelating agent having a structure in which the chelating functional group is bonded to the polystyrene may be charged in the form of particles into a column and used without any additional treatment. Alternatively, the chelating agent may be molded into a sheet under application of an appropriate pressure and then charged into a column.

The polystyrene may be crosslinked polystyrene prepared by high degree crosslinking for preventing elution of impurities. The crosslinking agent used may be a divinyl compound, such as divinylbenzene or divinylmethane.

Polystyrene having a large specific surface area is preferably used as an adsorbent. From this viewpoint, porous polystyrene may be used. Porous polystyrene can be prepared by polymerization of styrene with addition of a small amount of a non-solvent.

Crosslinked porous polystyrene (i.e., polystyrene having the aforementioned crosslinked structure and porous structure in combination) may be used.

As described above, the aforementioned carrier may be used in the form of particles, or may be molded and used in a fibrous, sheet, or cylindrical form. Alternatively, the carrier may be used in the form of a chelating resin film.

When polystyrene or crosslinked porous polystyrene is used in the form of particles, the particle diameter may be, for example, about 1 μm to 10 mm, or about 1 μm to 1 mm, or about 10 μm to 1 mm. When silica or a silica component-containing substance is used in the form of particles, the particle diameter may be, for example, about 1 μm to 1 mm, or about 1 μm to 500 μm, or about 10 μm to 100 μm.

The chelating agent (A) is preferably a metal adsorption agent containing a polymer substance having a unit structure of Formula (A-1) (hereinafter may be referred to as, for example, “metal adsorption agent of Formula (A-1)” or “chelating agent (chelating resin) of Formula (A-1)” or referred to simply as “Formula (A-1)”).

In the unit structure of Formula (A-1), A¹ is a unit structure forming silica, a silica component-containing substance, polystyrene, or crosslinked porous polystyrene serving as a carrier, and the glucamine-type functional group is bonded to A¹ via A². In the glucamine-type functional group, n is an integer of 1 to 10. In particular, n is 2 to 5, or 3 to 5. In the unit structure, n is particularly preferably 4.

A² is a single bond or a linking group that binds A¹ to the functional group, and the linking group is a C₁₋₁₀ alkylene group optionally containing an oxygen atom, a nitrogen atom, or a sulfur atom. In particular, A² is a C₁₋₅ or C₁₋₃ alkylene group. In particular, the functional group is bonded to the unit structure A¹ via a C₁ alkylene group.

In the chelating agent of Formula (A-1), the carrier is preferably polystyrene or crosslinked porous polystyrene. Thus, the unit structure A¹ can be formed of polystyrene.

The chelating resin of Formula (A-1) exhibits higher selectivity toward a metal ion having a larger valence. The chelating resin of Formula (A-1) can be obtained as, for example, trade name CRB03 or CRB05 available from Mitsubishi Chemical Corporation.

The chelating agent (B) is preferably a metal adsorption agent containing a polymer substance having at least one unit structure selected from the group consisting of unit structures of Formulae (B-1) to (B-18) (hereinafter may be referred to as, for example, “metal adsorption agent of Formulae (B-1) to (B-18)” or “chelating agent (chelating resin) of Formulae (B-1) to (B-18)” or referred to simply as “Formulae (B-1) to (B-18)”).

In the unit structure of Formula (B-1), B¹ is a unit structure forming silica, a silica component-containing substance, polystyrene, or crosslinked porous polystyrene serving as a carrier. B² is a single bond or a linking group that binds B¹ to the functional group, and the linking group is a C₁₋₁₀ alkylene group optionally containing an oxygen atom, a nitrogen atom, or a sulfur atom. In particular, B² is a C₁₋₁₀ or C₁₋₅ hydrocarbon group, and is particularly a C₃ hydrocarbon group. B¹ is particularly preferably silica or a silica component-containing substance.

In the present invention, the chelating agent (B) exhibits metal adsorption ability described below when used in combination with the chelating agent (A).

The metal adsorption agent containing a polymer substance having a unit structure of Formula (B-1) can trap many metals under various conditions. For example, the metal adsorption agent effectively traps metals such as Ag, Cu, Hg, Ir, Os, Pb, Pd, Ph, Ru, Sc, and Sn, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-1) can be obtained as, for example, a metal scavenger (trade name: Si-Thiol) available from SiliCycle Inc.

The metal adsorption agent containing a polymer substance having a unit structure of Formula (B-2) effectively traps, for example, metals such as Ag, Cu, Fe, Os, Pd, Rh, Sc, and Sn, ions of these metals, colloids of hydroxides of these metals, and colloids of oxides of these metals. In particular, the metal adsorption agent can effectively trap palladium ions in an organic solvent. The amount of the functional group contained in the metal adsorption agent may be about 0.1 mmol to 5 mmol relative to 1 g of the metal adsorption agent. The chelating agent of Formula (B-2) can be obtained as, for example, a metal scavenger (trade name: Si-Thiourea) available from SiliCycle Inc.

The metal adsorption agent containing a polymer substance having a unit structure of Formula (B-3) can trap many metals under various conditions. For example, the metal adsorption agent effectively traps metals such as Ca, Cd, Cr, Cs, Cu, Fe, Ir, La, Mg, Os, Pd, Pt, Rh, Ru, Sc, Sn, and Zn, ions of these metals, colloids of hydroxides of these metals, and colloids of oxides of these metals. In particular, the metal adsorption agent optimally traps Sn, ions of the metal, a colloid of a hydroxide of the metal, and a colloid of an oxide of the metal. The amount of the functional group contained in the metal adsorption agent may be about 0.1 mmol to 5 mmol relative to 1 g of the metal adsorption agent. The chelating agent of Formula (B-3) can be obtained as, for example, a metal scavenger (trade name: Muromac XMS-5418) available from Muromachi Chemicals Inc.

The metal adsorption agent containing a polymer substance having a unit structure of Formula (B-4) can trap many metals under various conditions. For example, the metal adsorption agent effectively traps metals such as Co, Ni, Cu, Ag, W, and Pb, ions of these metals, colloids of hydroxides of these metals, and colloids of oxides of these metals. In particular, the metal adsorption agent optimally traps Ru, ions of the metal, a colloid of a hydroxide of the metal, and a colloid of an oxide of the metal. The amount of the functional group contained in the metal adsorption agent may be about 0.1 mmol to 5 mmol relative to 1 g of the metal adsorption agent. The chelating agent of Formula (B-4) can be obtained as, for example, a metal scavenger (trade name: Si-TMT) available from SiliCycle Inc.

The metal adsorption agent containing a polymer substance having a unit structure of Formula (B-5) can trap many metals under various conditions. For example, the metal adsorption agent effectively traps metals such as Cd, Co, Cu, Fe, Ir, Ni, Os, Pd, Pt, Rh, Ru, Sc, and Zn, ions of these metals, colloids of hydroxides of these metals, and colloids of oxides of these metals. In particular, the metal adsorption agent optimally traps Ru and Pd, ions of these metal, colloids of hydroxides of these metals, and colloids of oxides of these metals. Also, the metal adsorption agent effectively traps complexes of these metals. The amount of the functional group contained in the metal adsorption agent may be about 0.1 mmol to 5 mmol relative to 1 g of the metal adsorption agent. The chelating agent of Formula (B-5) can be obtained as, for example, a metal scavenger (trade name: Si-DMT) available from SiliCycle Inc.

The metal adsorption agent containing a polymer substance having a unit structure of Formula (B-6) can trap many metals under various conditions. For example, the metal adsorption agent effectively traps metals such as Li, Mg, Al, K, Ti, Cr, Mn, Fe, Co, Ni, Cu, Zn, Zr, Ag, Sn, Ba, Pb, Na, Ca, V, and Cd, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-6) can be obtained as, for example, a metal scavenger (trade name: Si-SCX-2) available from SiliCycle Inc.

The metal adsorption agent containing a polymer substance having a unit structure of Formula (B-7) can trap many metals under various conditions. For example, the metal adsorption agent effectively traps metals such as Ag, Cu, Fe, Os, Pd, Rh, Sc, and Sn, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-7) can be obtained as, for example, a metal scavenger (trade name: IRC76-HG) available from ORGANO CORPORATION.

The metal adsorption agent containing a polymer substance having a unit structure of Formula (B-8) can trap many metals under various conditions. For example, the metal adsorption agent effectively traps metals such as Cd, Co, Cr, Cu, Fe, Hg, Ni, Pb, Pd, Pt, Ru, W, and Zn, ions of these metals, colloids of hydroxides of these metals, and colloids of oxides of these metals. In particular, the metal adsorption agent optimally traps metals such as Pd, Pt, Cr, W, and Zn, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-8) can be obtained as, for example, a metal scavenger (trade name: Si-Amine) available from SiliCycle Inc.

The metal adsorption agent containing a polymer substance having a unit structure of Formula (B-9) can trap many metals under various conditions. For example, the metal adsorption agent effectively traps metals such as Fe, Co, Ni, Cu, Zn, Ru, Rh, Pd,

Ag, Cd, Os, Pt, and Hg, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-9) can be obtained as, for example, trade name: CR20 available from Mitsubishi Chemical Corporation.

The metal adsorption agent containing a polymer substance having a unit structure of Formula (B-10) can trap many metals under various conditions. For example, the metal adsorption agent effectively traps metals such as Mg, Al, K, Ti, V, Cr, Mn, Fe, Ni, Cu, Zn, As, Zr, Mo, Ag, Cd, Sn, Ba, W, Pb, and Co, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-10) can be obtained as, for example, a metal scavenger (trade name: Si-Trisamine) available from SiliCycle Inc.

The metal adsorption agent containing a polymer substance having a unit structure of Formula (B-11) can trap many metals under various conditions. For example, the metal adsorption agent effectively traps metals such as Cd, Co, Cr, Cu, Fe, Ni, Os, Pd, Rh, W, and Zn, ions of these metals, colloids of hydroxides of these metals, and colloids of oxides of these metals. In particular, the metal adsorption agent optimally traps Fe, ions of the metal, a colloid of a hydroxide of the metal, and a colloid of an oxide of the metal. The amount of the functional group contained in the metal adsorption agent may be about 0.1 mmol to 5 mmol relative to 1 g of the metal adsorption agent. The chelating agent of Formula (B-11) can be obtained as, for example, a metal scavenger (trade name: Si-Imidazole) available from SiliCycle Inc.

The metal adsorption agent containing a polymer substance having a unit structure of Formula (B-12) can trap many metals under various conditions. For example, the metal adsorption agent effectively traps metals such as Co, Cr, Fe, and Pd, ions of these metals, colloids of hydroxides of these metals, and colloids of oxides of these metals. In particular, the metal adsorption agent optimally traps metals such as Co and Cr. The amount of the functional group contained in the metal adsorption agent may be about 0.1 mmol to 5 mmol relative to 1 g of the metal adsorption agent. The chelating agent of Formula (B-12) can be obtained as, for example, a metal scavenger (trade name: Si-TBD) available from SiliCycle Inc.

The metal adsorption agent containing a polymer substance having a unit structure of Formula (B-13) can trap many metals under various conditions. For example, the metal adsorption agent effectively traps metals such as Co, Cr, Fe, and Pd, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-13) can be obtained as, for example, a metal scavenger (trade name: S910) available from Purolite.

The metal adsorption agent containing a polymer substance having a unit structure of Formula (B-14) can trap many metals under various conditions. For example, the metal adsorption agent effectively traps metals such as Fe, Co, Ni, Cu, Zn, Ru, Rh, Pd, Ag, Cd, Os, Pt, and Hg, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-14) can be obtained as, for example, a metal scavenger (trade name: Si-PHI) available from SiliCycle Inc.

The metal adsorption agent containing a polymer substance having a unit structure of Formula (B-15) can trap many metals under various conditions. For example, the metal adsorption agent effectively traps metals such as Co, Cr, Fe, and Pd, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-15) can be obtained as, for example, a metal scavenger (trade name: MPA) available from Reaxa QuadraPure.

The metal adsorption agent containing a polymer substance having a unit structure of Formula (B-16) can trap many metals under various conditions. For example, the metal adsorption agent effectively traps metals such as Co, Cr, Cs, Fe, Ni, Os, Pd, Rh, Sc, and Sn, ions of these metals, colloids of hydroxides of these metals, and colloids of oxides of these metals. In particular, the metal adsorption agent optimally traps palladium metal. The amount of the functional group contained in the metal adsorption agent may be about 0.1 mmol to 5 mmol relative to 1 g of the metal adsorption agent. The chelating agent of Formula (B-16) can be obtained as, for example, a metal scavenger (trade name: Si-TAAcOH) available from SiliCycle Inc.

The metal adsorption agent containing a polymer substance having a unit structure of Formula (B-17) can trap many metals under various conditions. For example, the metal adsorption agent effectively traps metals such as Co, Cr, Fe, and Pd, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-17) can be obtained as, for example, a metal scavenger (trade name: IRC748) available from ORGANO CORPORATION.

The metal adsorption agent containing a polymer substance having a unit structure of Formula (B-18) can trap many metals under various conditions. For example, the metal adsorption agent effectively traps metals such as Co, Cr, Fe, and Pd, ions of these metals, colloids of hydroxides of these metals, and colloids of oxides of these metals. The amount of the functional group contained in the metal adsorption agent may be about 0.1 mmol to 5 mmol relative to 1 g of the metal adsorption agent. The chelating agent of Formula (B-18) can be obtained as, for example, a metal scavenger (trade name: IRC747UPS) available from ORGANO CORPORATION.

When a composition composed of a material containing an ionic compound is purified with a combination of the chelating agent (A) [e.g., Formula (A-1)] and the chelating agent (B) [e.g., Formulae (B-1) to (B-18)], the chelating agent (A) is preferably combined with the chelating agent (B) other than Formula (B-6).

When a composition composed of a material not containing an ionic compound is purified, the chelating agent (A) can be combined with any of the aforementioned chelating agents (B) [e.g., the above-exemplified chelating agents (B-1) to (B-18)].

The metal adsorption agent of the present invention for removing metal impurities contained in a solution may be used in any solution containing water or an organic solvent. In particular, the metal adsorption agent of the present invention is effectively used in a solution containing an organic solvent.

The pH of a solution to be treated is preferably around neutral pH, rather than highly acidic or alkaline pH. For example, the metal adsorption agent can be used in a solution having a pH of around 3 to 11, or around 4 to 10, or around 5 to 9, or around 6 to 8.

In the metal adsorption agent of the present invention, the proportions by mass of the chelating agent (A) and the chelating agent (B) may be 0.1 to 100:1, or 1 to 50:1, or 1 to 10:1.

Examples of the target metal impurity to be removed in a solution generally include, but are not limited to, metals other than alkali metals and alkaline earth metals. The target to be removed by adsorption is, for example, a polyvalent metal element, ions of the metal, a colloid of a hydroxide of the metal, or a colloid of an oxide of the metal. Specifically, the target to be removed is a polyvalent metal element belonging to periods 4 to 7 and groups 3 to 12, ions of the polyvalent metal, or a colloidal substance of a hydroxide or oxide of the metal. In some cases, such a polyvalent metal element is used in the form of 0-valent metal as a catalyst, and the metal remains in a product without being ionized.

The present invention is also directed to a material purification method comprising a step of preparing a to-be-purified material solution by dissolving or dispersing a to-be-purified material in a liquid; a step of causing the to-be-purified material solution to flow through a column filled with the aforementioned metal adsorption agent, to thereby prepare a purified solution; and a step of obtaining a purified material from the purified solution.

The to-be-purified material is a material containing, for example, naturally occurring metal impurities contained originally in a substance used as a raw material, metal impurities remaining even after high-degree purification treatment, or metal impurities derived from a catalyst used for synthesis of the raw material.

When a metal used as a catalyst remains as metal impurities, the impurities may be removed by a method involving purification of a product by distillation. However, when the product has a high boiling point, the product is difficult to be purified by distillation. In such a case, the method of the present invention is particularly effective.

When a product synthesized by using a metal catalyst is an ionic compound, the ionic compound may form a strong ionic bond with metal impurities derived from the catalyst, leading to difficulty in separation of the metal impurities. According to the method of the present invention, since the aforementioned metal adsorption agent is used, only the metal impurities can be selectively removed by adsorption without affecting the ionic product.

For example, an ionic catalyst may be added to a reaction system for efficiently performing a curing reaction using the dehydration reaction of a thermally crosslinkable resin. Such an ionic catalyst contains, as impurities, a metal such as Na, K, Al, Cr, Cu, Fe, Ni, Zn, or Ag, ions of the metal, a colloid of a hydroxide of the metal, or a colloid of an oxide of the metal. The metal impurities can be removed with the metal removal agent of the present invention.

Examples of the aforementioned ionic catalyst include an ammonium salt, a phosphine, a phosphonium salt, and a sulfonium salt.

Examples of the ammonium salt include:

a quaternary ammonium salt having a structure of the following Formula (D-1):

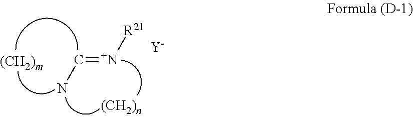

(wherein m is an integer of 2 to 11; n is an integer of 2 or 3; R²¹ is an alkyl group or an aryl group; N is a nitrogen atom; and Y⁻ is an anion);

a quaternary ammonium salt having a structure of the following Formula (D-2):

R²²R²³R²⁴R²⁵N⁺ Y⁻ Formula (D-2)

(wherein R²², R²³, R²⁴, and R²⁵ are each an alkyl group or an aryl group; N is a nitrogen atom; Y⁻ is an anion; and each of R²², R²³, R²⁴, and R²⁵ is bonded to the nitrogen atom via a C—N bond);

a quaternary ammonium salt having a structure of the following Formula (D-3):

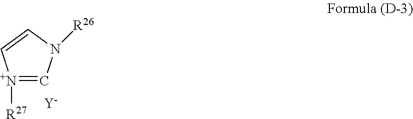

(wherein R²⁶ and R²⁷ are each an alkyl group or an aryl group; N is a nitrogen atom; and Y⁻ is an anion);

a quaternary ammonium salt having a structure of the following Formula (D-4):

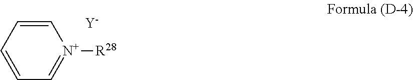

(wherein R²⁸ is an alkyl group or an aryl group; N is a nitrogen atom; and Y⁻ is an anion);

a quaternary ammonium salt having a structure of the following Formula (D-5):

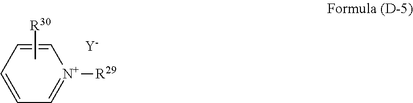

(wherein R²⁹ and R³⁰ are each an alkyl group or an aryl group; N is a nitrogen atom; and Y⁻ is an anion); and

a tertiary ammonium salt having a structure of the following Formula (D-6):

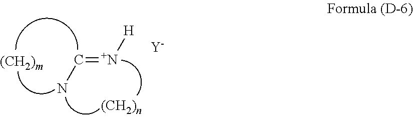

(wherein m is an integer of 2 to 11; n is an integer of 2 or 3; N is a nitrogen atom; H is a hydrogen atom; and Y⁻ is an anion).

Examples of the phosphonium salt include a quaternary phosphonium salt of the following Formula (D-7):

R³¹R32R³³R³⁴P⁺ Y⁻ Formula (D-7)

(wherein R³¹, R³², R³³, and R³⁴ are each an alkyl group or an aryl group; P is a phosphorus atom; Y⁻ is an anion; and each of R³¹, R³², R³³, and R³⁴ is bonded to the phosphorus atom via a C—P bond).

Examples of the sulfonium salt include a tertiary sulfonium salt of the following Formula (D-8):

R³⁵R³⁶ R³⁷ S⁺ Y⁻ Formula (D-8)

(wherein R³⁵, R³⁶, and R³⁷ are each an alkyl group or an aryl group; S is a sulfur atom; Y⁻ is an anion; and each of R³⁵, R³⁶, and R³⁷ is bonded to the sulfur atom via a C—S bond).

The compound of Formula (D-1) is a quaternary ammonium salt derived from an amine. In Formula (D-1), m is an integer of 2 to 11, and n is an integer of 2 or 3. R²¹ of the quaternary ammonium salt is a C₁₋₁₈ alkyl or aryl group, preferably a C₂₋₁₀ alkyl or aryl group. Examples of R²¹ include linear alkyl groups, such as ethyl group, propyl group, and butyl group, benzyl group, cyclohexyl group, cyclohexylmethyl group, and dicyclopentadienyl group. Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻).

The compound of Formula (D-2) is a quaternary ammonium salt having a structure of R²²R²³R²⁴R²⁵N⁺Y⁻. R²², R²³, R²⁴, and R²⁵ of the quaternary ammonium salt are each a C₁₋₁₈ alkyl or aryl group. Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. In Formula (D-3), R²⁶ and R²⁷ are each a C₁₋₁₈ alkyl or aryl group, and the total number of carbon atoms of R²⁶ and R²⁷ is preferably 7 or more. Examples of R²⁶ include methyl group, ethyl group, propyl group, phenyl group, and benzyl group. Examples of R²⁷ include benzyl group, octyl group, and octadecyl group.

Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound can be produced through, for example, reaction between an imidazole compound (e.g., 1-methylimidazole or 1-benzylimidazole) and an alkyl or aryl halide (e.g., benzyl bromide or methyl bromide).

The compound of Formula (D-4) is a quaternary ammonium salt derived from pyridine. In Formula (D-4), R²⁸ is a C₁₋₁₈ alkyl or aryl group, preferably a C₄₋₁₈ alkyl or aryl group. Examples of R²⁸ include butyl group, octyl group, benzyl group, and lauryl group. Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound can be produced through, for example, reaction between pyridine and an alkyl or aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. In Formula (D-5), R²⁹ is a C₁₋₁₈ alkyl or aryl group, preferably a C₄₋₁₈ alkyl or aryl group. Examples of R²⁹ include methyl group, octyl group, lauryl group, and benzyl group. R³⁰ is a C₁₋₁₈ alkyl or aryl group, and, for example, R³⁰ is a methyl group when the compound is a quaternary ammonium salt derived from picoline. Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound can be produced through, for example, reaction between a substituted pyridine (e.g., picoline) and an alkyl or aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine. In Formula (D-6), m is an integer of 2 to 11, and n is an integer of 2 or 3. Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The compound can be produced through, for example, reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each a C₁₋₁₈ alkyl or aryl group. Three of the four substituents R³¹ to R³⁴ are preferably a phenyl group or a substituted phenyl group, such as a phenyl group or a tolyl group. The remaining one substituent is a C₁₋₁₈ alkyl or aryl group. Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halides and tetra-n-propylphosphonium halides; trialkylbenzylphosphonium halides, such as triethylbenzylphosphonium halides; triphenylmonoalkylphosphonium halides, such as triphenylmethylphosphonium halides and triphenylethylphosphonium halides; triphenylbenzylphosphonium halides; tetraphenylphosphonium halides; tritolylmonoarylphosphonium halides; and tritolylmonoalkylphosphonium halides (wherein the halogen atom is a chlorine atom or a bromine atom). Particularly preferred are triphenylmonoalkylphosphonium halides, such as triphenylmethylphosphonium halides and triphenylethylphosphonium halides;

triphenylmonoarylphosphonium halides, such as triphenylbenzylphosphonium halides; tritolylmonoarylphosphonium halides, such as tritolylmonophenylphosphonium halides; and tritolylmonoalkylphosphonium halides, such as tritolylmonomethylphosphonium halides (wherein the halogen atom is a chlorine atom or a bromine atom).

Examples of the phosphine include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each a C₁₋₁₈ alkyl or aryl group. Three of the four substituents R³⁵ to R³⁷ are preferably a phenyl group or a substituted phenyl group, such as a phenyl group or a tolyl group. The remaining one sub stituent is a C₁₋₁₈ alkyl or aryl group. Examples of the anion (Y⁻) include halogen ions, such as chlorine ion (Cl⁻), bromine ion (Br⁻), and iodine ion (I⁻); and acid groups, such as carboxylate (—COO⁻), sulfonate (—SO₃⁻), alcoholate (—O⁻), maleate anion, and nitrate anion. This compound is commercially available, and examples of the compound include trialkylsulfonium halides, such as tri-n-butylsulfonium halides and tri-n-propylsulfonium halides; dialkylbenzylsulfonium halides, such as diethylbenzylsulfonium halides; diphenylmonoalkylsulfonium halides, such as diphenylmethylsulfonium halides and diphenylethylsulfonium halides; triphenylsulfonium halides (wherein the halogen atom is a chlorine atom or a bromine atom); trialkylphosphonium carboxylates, such as tri-n-butylsulfonium carboxylate and tri-n-propylsulfonium carboxylate; dialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halides and triphenylsulfonium carboxylate are preferably used.

Next will be described the case where the catalyst itself becomes metal impurities.

For example, when a catalyst is used, the catalyst may be in the form of a homogeneous catalyst dissolved in a solution, or a non-homogeneous catalyst used in a state of solid phase.

The non-homogeneous catalyst is formed of zeolite supporting, for example, platinum, palladium, rhodium, or iridium having a size of about 1 to 100 nm, and can be removed from a reaction mixture by filtration.

In contrast, the homogeneous catalyst is prepared by dissolving a catalyst component in a reaction system, and removal of the catalyst requires adsorption. For example, a platinum catalyst, which is used for hydrosilylation of a silicon compound, is one of residual catalysts that are difficult to be removed with an ion-exchange resin. Such a catalyst can be removed with the metal adsorption agent of the present invention.

A to-be-purified material solution prepared by dissolving or dispersing a to-be-purified material in a liquid contains metal impurities derived from the to-be-purified material in an amount of about several ppm to several hundreds of ppm. When the metal adsorption agent of the present invention is applied to the solution, the amount of the metal impurities contained in the solution can be reduced to several ppb to several hundreds of ppb, or several ppt to several hundreds of ppt. The metal adsorption agent can be applied so that the amount is reduced to 500 ppt or less.

The present invention is also directed to a method for producing a material solution containing a reduced amount of impurities. Specifically, the present invention relates to a method for producing a material solution containing a reduced amount of impurities, the method comprising a step of circulating a to-be-purified material solution containing a to-be-purified material dissolved or dispersed in a liquid in a system provided by connection with a pipe between a tank containing the to-be-purified material solution and a column filled with the aforementioned metal adsorption agent, to thereby remove, by adsorption, ions of a metal or a colloidal substance of the metal contained in the to-be-purified material solution, thereby preparing a purified material solution containing a reduced amount of impurities. A portion of the flow channel formed of the pipe connecting the tank with the column is provided with a port for sampling the purified material solution containing the purified material. Thus, the port can be opened/closed with a valve, and the purified material solution can be taken out from the flow channel connected with the pipe. A portion of the pipe can be provided with a pump, and the to-be-purified material solution can be circulated through the pump. Preferably, the to-be-purified material solution is circulated in a closed system for avoiding intrusion of impurities from the outside.

In the present invention, when a composition composed of a material containing no ionic substance is purified, the to-be-purified material solution can be caused to flow through an ion-exchange resin before or after (preferably before and after) the to-be-purified material solution is caused to flow through the metal adsorption agent containing the chelating agent (A) and the chelating agent (B). The to-be-purified material solution can be brought into contact with the ion-exchange resin a plurality of times by circulation of the solution, to thereby efficiently reduce the amount of impurities.

Examples of usable ion-exchange resins include a cation-exchange resin and an anion-exchange resin. These resins may be used alone or in combination.

Examples of the cation-exchange resin include a strongly acidic ion-exchange resin (functional group having sulfonate) and a weakly acidic ion-exchange resin (functional group having a carboxyl group). Examples of the anion-exchange resin include a strongly basic ion-exchange resin (functional group having a quaternary ammonium group) and a weakly basic ion-exchange resin (functional group having a tertiary amino group).

The ion-exchange resin may be used in the form of particles, or may be molded and used in a fibrous, sheet, or cylindrical form. Alternatively, the ion-exchange resin may be used in a film form. When the ion-exchange resin is used in the form of particles; for example, particles prepared by binding the aforementioned functional group to a carrier such as polystyrene or crosslinked porous polystyrene, the particles may have a particle diameter of, for example, about 1 μm to 10 mm, or about 1 μm to 1 mm, or about 10 μm to 1 mm.

In the present invention, the liquid (water or a solvent) that dissolves or disperses the to-be-purified material may be a previously purified liquid. When the to-be-purified material solution (i.e., composition solution before purification) is prepared by using a previously purified liquid, the amount of impurities is more efficiently and significantly reduced in the material solution (i.e., composition solution after purification).

The solvent can be removed from the material solution containing a reduced amount of impurities, to thereby prepare a material containing a reduced amount of impurities. The material solution containing a reduced amount of impurities may be used, as is, as a material-containing composition solution.

In the case where a previously purified liquid is used, the purification of the liquid is performed by the following method: a method in which the liquid is previously purified in a closed system for purifying the to-be-purified material solution containing the to-be-purified material, or a method in which the liquid is previously purified in a closed system different from the aforementioned closed system, and the purified liquid is fed via a pipe to the closed system for purifying the to-be-purified material solution containing the to-be-purified material.

The former method corresponds to the case where the liquid (water or a solvent) and the to-be-purified material solution containing the to-be-purified material are purified in the same apparatus; specifically, the material is added to the liquid (water or a solvent) after purification thereof, and then the resultant to-be-purified material solution is purified in the same apparatus.

The latter method corresponds to the case where the liquid (water or a solvent) and the to-be-purified material solution containing the to-be-purified material are purified in different apparatuses; specifically, the liquid (water or a solvent) is purified in a purification system, and then the purified liquid is temporarily stored in a tank, or directly fed via a pipe to another purification system for purifying the to-be-purified material solution containing the to-be-purified material.

In the present invention, the to-be-purified material solution may be a coating composition used in a lithographic process for semiconductor production.

The coating composition used in a lithographic process contains at least a resin for lithography and a solvent, and may further contain an acid generator, an acid diffusion controlling agent, a crosslinking agent, a crosslinking catalyst, or a surfactant.

Examples of the resin for lithography include resist resins suitable for fine processing with ultraviolet rays such as g-rays and i-rays, a KrF excimer laser, an ArF excimer laser, an F₂ excimer laser, a 172-nm excimer laser, EUV light, and electron beams; materials for forming an upper layer film (resist upper layer film) and an underlayer film (resist underlayer film or anti-reflective coating) in a multilayer resist process; and oxide film-forming materials.

The resin for lithography may be an organic resin (e.g., acrylate resin, methacrylate resin, hydroxystyrene resin, or novolac resin) or a silicon-containing material (e.g., a resin having a polysiloxane skeleton).

The polymer used as the resin for lithography may have a weight average molecular weight of, for example, 600 to 1,000,000 or 600 to 200,000.

In the coating composition, the total solid content may be, for example, 0.1 to 70% by mass or 0.1 to 60% by mass. The term “total solid content” as used herein corresponds to the amount of all components of the coating composition used for lithography, except for the amount of a solvent. For the sake of convenience, the total solid content includes a liquid component.

The aforementioned polymer used as the resin for lithography may account for, for example, 1 to 100% by mass, or 1 to 99.9% by mass, or 50 to 99.9% by mass, or 50 to 95% by mass, or 50 to 90% by mass of the total solid content.

The crosslinking agent that can be incorporated into the coating composition is, for example, a melamine-based crosslinking agent, a substituted urea-based crosslinking agent , or a polymer-based crosslinking agent thereof. The crosslinking agent is preferably a crosslinking agent having at least two crosslinking-forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or methoxymethylated thiourea. A condensate of such a compound may also be used.

The aforementioned crosslinking agent may be a crosslinking agent having high thermal resistance. The crosslinking agent having high thermal resistance is preferably a compound containing a crosslinking-forming substituent having an aromatic ring (e.g., a benzene ring or a naphthalene ring) in the molecule.

When the crosslinking agent is used, the amount of the crosslinking agent added may vary depending on, for example, the type of a coating solvent used, the type of an underlying substrate used, the viscosity of a solution required, or the shape of a film required. The amount of the crosslinking agent is, for example, 0.001 to 80% by mass, preferably 0.01 to 50% by mass, more preferably 0.05 to 40% by mass, relative to the total solid content of the coating composition. Such a crosslinking agent may cause a crosslinking reaction by its self-condensation. When a crosslinkable substituent is present in the aforementioned resin for lithography (polymer), such a crosslinking agent may cause a crosslinking reaction with the crosslinkable substituent.

Examples of the catalyst (crosslinking catalyst) that can be incorporated into the coating composition and promotes a crosslinking reaction include acidic compounds, such as p-toluenesulfonic acid, trifluoromethanesulfonic acid, pyridinium p-toluenesulfonate, salicylic acid, 5-sulfosalicylic acid, 4-phenolsulfonic acid, pyridinium 4-phenolsulfonate, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid; and/or thermal acid generators, such as 2,4,4,6-tetrabromocyclohexadienone, benzoin tosylate, 2-nitrobenzyl tosylate, and other organic sulfonic acid alkyl esters.

When the crosslinking catalyst is used, the amount thereof is, for example, 0.0001 to 20% by mass, preferably 0.0005 to 10% by mass, more preferably 0.01 to 3% by mass, relative to the total solid content of the coating composition.

The acid generator incorporated into the coating composition may be a photoacid generator. Preferred examples of the photoacid generator include onium salt photoacid generators, such as bis(4-t-butylphenyl)iodonium trifluoromethanesulfonate and triphenylsulfonium trifluoromethanesulfonate; halogen-containing compound photoacid generators, such as phenyl-bis(trichloromethyl)-s-triazine; and sulfonate photoacid generators, such as benzoin tosylate and N-hydroxysuccinimide trifluoromethanesulfonate.

When the aforementioned photoacid generator is used, the amount thereof is 0.2 to 10% by mass, preferably 0.4 to 5% by mass, relative to the total solid content of the coating composition.

The acid diffusion controlling agent incorporated into the coating composition may be a nitrogen-containing organic compound; i.e., a basic compound (quencher).

The aforementioned nitrogen-containing organic compound is suitably a compound that can reduce the rate of diffusion of an acid generated from the acid generator within a resist film. The incorporation of the nitrogen-containing organic compound can reduce the rate of diffusion of the acid within the resist film, leading to an improvement in resolution, resulting in a reduction in sensitivity change after light exposure, a reduction in substrate- or environment dependence, or an improvement in, for example, exposure margin or pattern profile.

Examples of the nitrogen-containing organic compound (quencher) include primary, secondary, and tertiary aliphatic amines, hybrid amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amides, imides, carbamates, ammonia, ammonium salts, and sulfonium salts.

Examples of the surfactant that can be incorporated into the coating composition include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as EFTOP EF301, EF303, and EF352 (trade name, available from Tohkem Products Corporation (current name: Mitsubishi Materials Electronic Chemicals Co., Ltd.)), MEGAFAC F171, F173, R-30, and R-30N (trade name, available from DIC Corporation), Fluorad FC430 and FC431 (trade name, available from Sumitomo 3M Limited), and Asahi Guard AG710 and SURFLON S-382, SC101, SC102, SC103, SC104, SC105, and SC106 (trade name, available from Asahi Glass Co., Ltd.); and Organosiloxane Polymer KP341 (available from Shin-Etsu Chemical Co., Ltd.).

When the surfactant is used, the amount thereof is generally 2.0% by mass or less, preferably 1.0% by mass or less, relative to the total solid content of the coating composition used for lithography. These surfactants may be added alone, or in combination of two or more species.

When the to-be-purified material solution (e.g., coating composition) contains water or an organic solvent, the liquid (i.e., solvent) that dissolves or disperses the to-be-purified material is selected from, for example, water; aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and trimethylbenzene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, pentanediol-2,4, 2-methylpentanediol-2,4, hexanediol-2,5, heptanediol-2,4, 2-ethylhexanediol-1,3, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, propylene glycol monomethyl ether acetate, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents may be used alone or in combination of two or more species.

Other examples include methylcellosolve acetate, ethylcellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol mooethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methybutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone.

### EXAMPLES

The present invention will next be described in more detail by way of examples. However, the present invention should not be construed as being limited to the following examples.

(Test for Adsorption of Target Salt-Type Acid Catalyst to Chelating Material)

A polyethylene-made syringe having a total volume of 15 mL was charged with a chelating material described below, and polyethylene filters were attached to the upper and lower portions of the chelating material, to thereby prepare a syringe for evaluation of adsorption test (Examples 1 to 14 and Comparative Examples 1 to 4). A target material described below was dissolved in PGME (propylene glycol monomethyl ether) to thereby prepare a 1% by mass PGME solution.

The PGME solution was filtered in increments of 10 g with the syringe for evaluation of adsorption test, and the target material concentration of the filtrate was quantified by LC (liquid chromatography) after filtration of 50 g of the solution, to thereby evaluate the adsorption of the target material to the chelating material.

The filterability of the chelating material was evaluated as “Good” (i.e., no adsorption) when the target material concentration of the filtrate was 95% or more of that of the solution before the filtration.

(Test for Removal of Metal from Target Material)

A polyethylene-made syringe having a total volume of 30 mL was charged with a chelating material described below, and polyethylene filters were attached to the upper and lower portions of the chelating material, to thereby prepare a syringe for evaluation of metal removal (Examples 1 to 14 and Comparative Examples 1 to 4). A target material described below was dissolved in PGME to thereby prepare a 0.5% by mass PGME solution.

The PGME solution containing the target material and metals dissolved therein was filtered in increments of 10 g with the syringe for evaluation of metal removal, and the filtrate was analyzed by ICP-MS after filtration of 50 g of the solution, to thereby calculate the amounts of metals. The metal removal ability of the chelating material was evaluated as “Good” when the concentrations of Na, K, Al, Cr, Cu, Fe, Ni, Zn, and Ag were reduced.

Tables 1 and 2 show the results of the test for adsorption of the target material to the chelating resin, as well as the results of the test for removal of metals from the target material.

The target material used was a quaternary ammonium salt of trifluoromethanesulfonic acid (trade name: TAG2689 (thermal acid generator)) available from King (USA).

In Table 1, Metal adsorption agent 1 contains 30 g of Formula (A-1) and 5 g of Formula (B-1).

Metal adsorption agent 2 contains 30 g of Formula (A-1) and 5 g of Formula (B-2).

Metal adsorption agent 3 contains 30 g of Formula (A-1) and 5 g of Formula (B-3).

Metal adsorption agent 4 contains 30 g of Formula (A-1) and 5 g of Formula (B-4).

Metal adsorption agent 5 contains 30 g of Formula (A-1) and 5 g of Formula (B-5).

Metal adsorption agent 6 contains 30 g of Formula (A-1) and 5 g of Formula (B-7).

Metal adsorption agent 7 contains 30 g of Formula (A-1) and 5 g of Formula (B-9).

Metal adsorption agent 8 contains 30 g of Formula (A-1) and 5 g of Formula (B-10).

Metal adsorption agent 9 contains 30 g of Formula (A-1) and 5 g of Formula (B-11).

Metal adsorption agent 10 contains 30 g of Formula (A-1) and 5 g of Formula (B-13).

Metal adsorption agent 11 contains 30 g of Formula (A-1) and 5 g of Formula (B-14).

Metal adsorption agent 12 contains 30 g of Formula (A-1) and 5 g of Formula (B-15).

Metal adsorption agent 13 contains 30 g of Formula (A-1) and 5 g of Formula (B-17).

Metal adsorption agent 14 contains 30 g of Formula (A-1) and 5 g of Formula (B-18).

In Table 2, Comparative metal adsorption agent 1 contains 5 g of (B-8).

Comparative metal adsorption agent 2 contains 5 g of (B-12).

Comparative metal adsorption agent 3 contains 5 g of (B-16).

Comparative metal adsorption agent 4 contains 5 g of (A-1).

The following chelating agents: Formula (A-1), Formulae (B-1) to (B-5), and Formulae (B-7) to (B-18) were used in the aforementioned Metal adsorption agents 1 to 14 and Comparative metal adsorption agents 1 to 4.

Trade name CRB03 is the chelating agent (Formula (A-1)) available from Mitsubishi Chemical Corporation.

Trade name Si-Thiol is the chelating agent (Formula (B-1)) available from SiliCycle Inc.

Trade name Si-Thiourea is the chelating agent (Formula (B-2)) available from SiliCycle Inc.

Trade name Muromac XMS-5418 is the chelating agent (Formula (B-3)) available from Muromachi Chemicals Inc.

Trade name Si-TMT is the chelating agent (Formula (B-4)) available from SiliCycle Inc.

Trade name Si-DMT is the chelating agent (Formula (B-5)) available from SiliCycle Inc.

Trade name IRC76-HG is the chelating agent (Formula (B-7)) available from ORGANO CORPORATION.

Trade name Si-Amine is the chelating agent (Formula (B-8)) available from SiliCycle Inc.

Trade name CR20 is the chelating agent (Formula (B-9)) available from Mitsubishi Chemical Corporation.

Trade name Si-Trisamine is the chelating agent (Formula (B-10)) available from SiliCycle Inc.

Trade name Si-Imidazole is the chelating agent (Formula (B-11)) available from SiliCycle Inc.

Trade name Si-TBD is the chelating agent (Formula (B-12)) available from SiliCycle Inc.

Trade name 5910 is the chelating agent (Formula (B-13)) available from Purolite.

Trade name Si-PHI is the chelating agent (Formula (B-14)) available from SiliCycle Inc.

Trade name MPA is the chelating agent (Formula (B-15)) available from Reaxa QuadraPure™.

Trade name Si-TAAcOH is the chelating agent (Formula (B-16)) available from SiliCycle Inc.

Trade name IRC748 is the chelating agent (Formula (B-17)) available from ORGANO CORPORATION.

Trade name IRC747UPS is the chelating agent (Formula (B-18)) available from ORGANO CORPORATION.

TABLE 1

| | | | | Metal |
|---|---|---|---|---|
| | Target | | | removal |
| Example | material | Metal adsorption agent | Filterability | ability |
| 1 | TAG2689 | Metal adsorption agent 1 | Good | Good |
| 2 | TAG2689 | Metal adsorption agent 2 | Good | Good |
| 3 | TAG2689 | Metal adsorption agent 3 | Good | Good |
| 4 | TAG2689 | Metal adsorption agent 4 | Good | Good |
| 5 | TAG2689 | Metal adsorption agent 5 | Good | Good |
| 6 | TAG2689 | Metal adsorption agent 6 | Good | Good |
| 7 | TAG2689 | Metal adsorption agent 7 | Good | Good |
| 8 | TAG2689 | Metal adsorption agent 8 | Good | Good |
| 9 | TAG2689 | Metal adsorption agent 9 | Good | Good |
| 10 | TAG2689 | Metal adsorption agent 10 | Good | Good |
| 11 | TAG2689 | Metal adsorption agent 11 | Good | Good |
| 12 | TAG2689 | Metal adsorption agent 12 | Good | Good |
| 13 | TAG2689 | Metal adsorption agent 13 | Good | Good |
| 14 | TAG2689 | Metal adsorption agent 14 | Good | Good |

TABLE 2

| | | | | Metal |
|---|---|---|---|---|
| Comparative | Target | | | removal |
| Example | material | Metal adsorption agent | Filterability | ability |
| 1 | TAG2689 | Comparative metal adsorption agent 1 | Good | Poor |
| 2 | TAG2689 | Comparative metal adsorption agent 2 | Good | Poor |
| 3 | TAG2689 | Comparative metal adsorption agent 3 | Good | Poor |
| 4 | TAG2689 | Comparative metal adsorption agent 4 | Good | Poor |

### INDUSTRIAL APPLICABILITY

According to the present invention, metal impurities can be removed from a coating composition used for a semiconductor production process (which composition contains a to-be-purified material dissolved therein) by using a metal adsorption agent containing not a single chelating resin but a combination of specific chelating resins without causing adsorption or denaturation of components contained in the composition, to thereby prepare a purified material composition having high purity.

1. A metal adsorption agent for removing metal impurities contained in a solution, the metal adsorption agent comprising a chelating agent (A) and a chelating agent (B), wherein
the chelating agent (A) is a metal adsorption agent containing a carrier having a glucamine-type functional group, and
the chelating agent (B) is a metal adsorption agent containing a carrier having a thiol group, a thiourea group, an amino group, a triazabicyclodecene-inducing group, a thiouronium group, an imidazole group, a sulfonate group, a hydroxy group, an aminoacetate group, an amidoxime group, an aminophosphate group, or any combination of these groups.

2. The metal adsorption agent according to claim 1, wherein the carrier of each of the chelating agent (A) and the chelating agent (B) is silica, a silica component-containing substance, polystyrene, or crosslinked porous polystyrene.

3. The metal adsorption agent according to claim 1, wherein the chelating agent (A) is a metal adsorption agent containing a polymer substance having a unit structure of the following Formula (A-1): 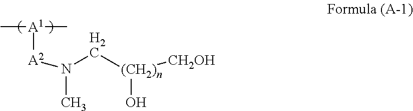
(wherein n is an integer of 1 to 10; A¹ is a unit structure forming silica, a silica component-containing substance, polystyrene, or crosslinked porous polystyrene serving as a carrier; A² is a single bond or a linking group that binds A¹ to the functional group; and the linking group is a C₁₋₁₀ alkylene group optionally containing an oxygen atom, a nitrogen atom, or a sulfur atom).

4. The metal adsorption agent according to claim 1, wherein the chelating agent (B) is a metal adsorption agent containing a polymer substance having one or more unit structures selected from the group consisting of unit structures of the following Formulae (B-1) to (B-18): 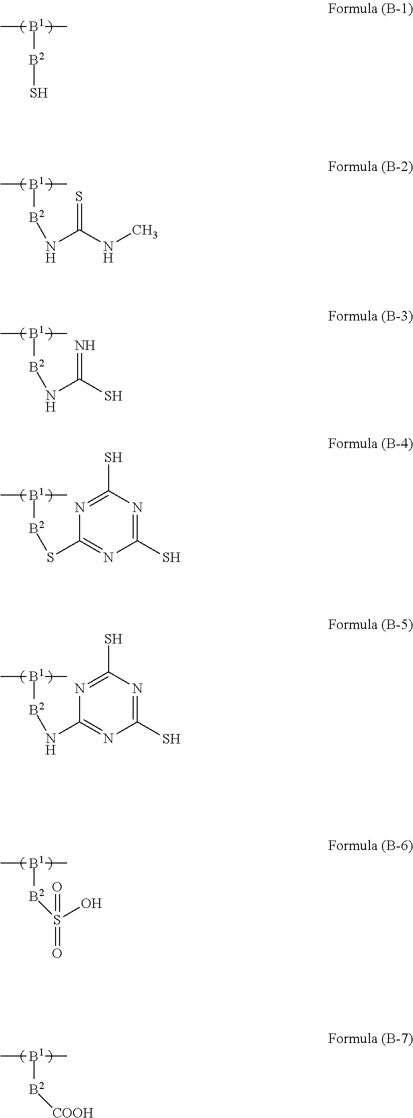 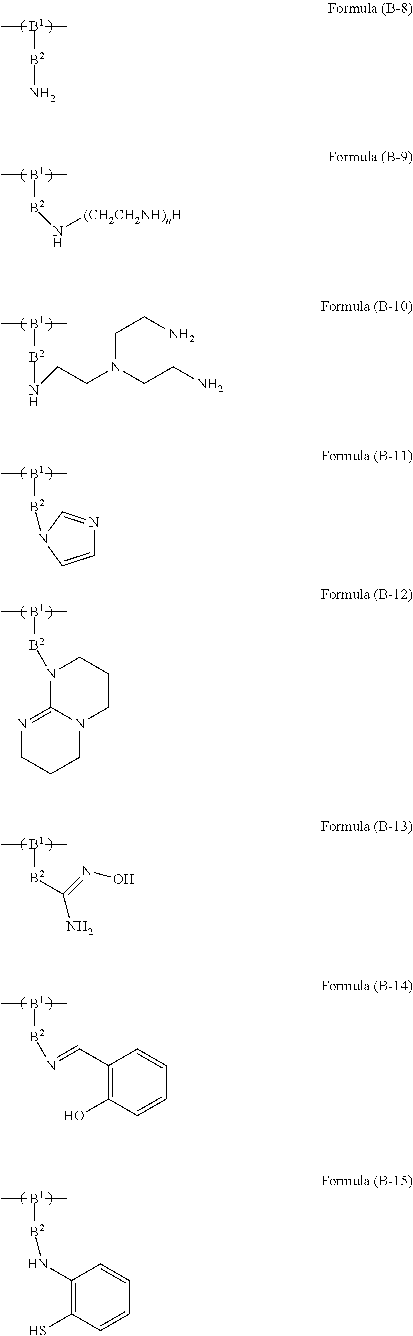 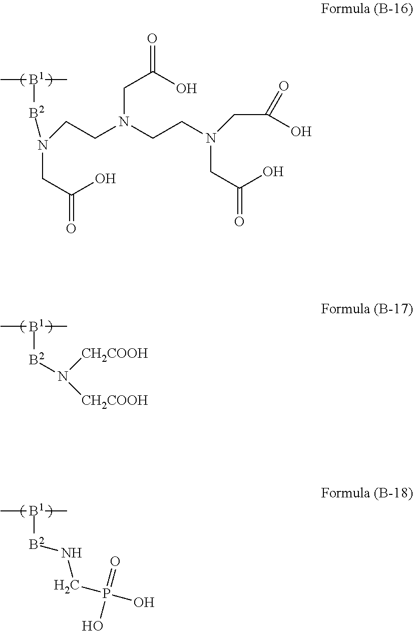
(wherein B¹ is a unit structure forming silica, a silica component-containing substance, polystyrene, or crosslinked porous polystyrene serving as a carrier; B² is a single bond or a linking group that binds B¹ to the functional group; and the linking group is a C₁₋₁₀ alkylene group optionally containing an oxygen atom, a nitrogen atom, or a sulfur atom).

5. The metal adsorption agent according to claim 1, wherein the solution is a solution containing water or an organic solvent.

6. The metal adsorption agent according to claim 1, wherein the metal adsorption agent comprises the chelating agent (A) and the chelating agent (B) in proportions by mass of 0.1 to 100:1.

7. The metal adsorption agent according to claim 1, wherein the metal to be removed is a polyvalent metal belonging to periods 4 to 7 and groups 3 to 12, ions of the polyvalent metal, or a colloidal substance of a hydroxide or oxide of the metal.

8. A material purification method comprising:
a step of preparing a to-be-purified material solution by dissolving or dispersing a to-be-purified material in a liquid;
a step of causing the to-be-purified material solution to flow through a column filled with the metal adsorption agent according to claim 1, to thereby prepare a purified solution; and
a step of obtaining a purified material from the purified solution.

9. A method for producing a material solution containing a reduced amount of impurities, the method comprising:
a step of circulating a to-be-purified material solution containing a to-be-purified material dissolved or dispersed in a liquid in a system provided by connection with a pipe between a tank containing the to-be-purified material solution and a column filled with the metal adsorption agent according to claim 1, to thereby remove, by adsorption, a polyvalent metal element, ions of the metal, or a colloidal substance of the metal contained in the to-be-purified material solution, thereby preparing a purified material solution containing a reduced amount of impurities.

10. The method for producing a material solution containing a reduced amount of impurities according to claim 9, wherein the liquid that dissolves or disperses the to-be-purified material is water or an organic solvent.

11. The method for producing a material solution containing a reduced amount of impurities according to claim 9, wherein the to-be-purified material solution is circulated in a closed system.

12. The method for producing a material solution containing a reduced amount of impurities according to claim 9, wherein the method comprises a step of causing the to-be-purified material solution to flow through an ion-exchange resin before and after causing the to-be-purified material solution to flow through the metal adsorption agent comprising the chelating agent (A) and the chelating agent (B).

13. The method for producing a material solution containing a reduced amount of impurities according to claim 9, wherein the liquid that dissolves or disperses the to-be-purified material is a previously purified liquid.

14. The method for producing a material solution containing a reduced amount of impurities according to claim 9, wherein the purification of the liquid is previously performed in a closed system for purifying the to-be-purified material solution containing the to-be-purified material, or the purification of the liquid is previously performed in a closed system different from the closed system described above, and the purified liquid is fed via a pipe to the closed system for purifying the to-be-purified material solution containing the to-be-purified material.

15. The method for producing a material solution containing a reduced amount of impurities according to claim 9, wherein the to-be-purified material solution is a coating composition used in a lithographic process for semiconductor production.

16. The method for producing a material solution containing a reduced amount of impurities according to claim 9, wherein the method is performed until the amount of the metal ions or the metal colloidal substance is reduced to 500 ppt or less in the to-be-purified material solution containing the to-be-purified material dissolved or dispersed in the liquid.
